(19) United States
(12) Patent Application Publication
(10) Pub. No.: US 2005/0276122 A1
(43) Pub. Date: Dec. 15, 2005

(54) Efficient recovery of failed memory cell

(76) Inventor: Mitsuo Kaibara, Hyogo (JP)

Correspondence Address: DICKSTEIN SHAPIRO MORIN & OSHINSKY LLP, 2101 L Street, NW, Washington, DC, 20037, US

(21) Appl. No.: 11/150,345

(22) Filed: Jun. 13, 2005

(30) Foreign Application Priority Data
Jun. 14, 2004 (JP) NO. 2004-176104

(51) Int. Cl. G11C 16/04

(52) U.S. Cl. 365/189.01

(57) ABSTRACT

A semiconductor memory device includes a memory match unit configured to check whether memory information identifying the semiconductor memory device matches external memory information supplied from an exterior, a repair match unit configured to check, in response to a finding of a match by the memory match unit, whether an access address matches a repair address indicative of a failed cell position, and a control unit configured to perform a control operation to access a spare memory in response to a finding of a match by the repair match unit.

### BACKGROUND OF THE INVENTION

1. Field of the Invention

The present invention relates to a semiconductor memory device, a fuse box circuit, and a semiconductor integrated circuit comprised of such semiconductor memory device and fuse box circuit.

2. Description of the Related Art

It is generally known that when memories are integrated on a chip, an increase in the memory size causes a product yield to deteriorate due to wafer defects or the like. In recent years, with an increase in the memory size, it has been becoming more and more difficult to manufacture all the memory cells without defects.

When memories such as static random access memories (hereinafter denoted as SRAMs) are manufactured, conventionally, spare memory cells for recovery purposes are provided separately from the routine memory cells for the purpose of increasing the yield. When there is a failure or defect in a routine memory cell, a properly operating spare memory cell is used as a replacement.

When a properly operating spare memory cell replaces a defect cell of the routine memory, a fuse circuit is utilized. To this end, such a fuse circuit needs to be provided on the chip.

In an SOC (system-on-a-chip) which has a large number of memories arranged on the chip, the provision of a separate fuse circuit for each memory results in the entirety of the fuse circuits becoming bulky on the chip, causing an increase in the chip size.

Provision is generally made to recover a large-size memory by use of fuse circuits while refraining from recovering a small-size memory by use of fuse circuits. In an SOC or the like which uses a large number of small-size memories, there has always been a drawback in that the yield is low.

FIG. 10 is a drawing showing the basic configuration of a related-art memory.

A memory 100 shown in FIG. 10 includes a memory array 101 for storing data, a row decoder 102 for selecting a row of the memory array 101 in response to a row address signal, a column decoder 103 for selecting a column of the memory array 101 in response to a column address signal, and an address buffer 104 for generating a row address signal and column address signal supplied to the row decoder 102 and column decoder 103, respectively, in response to access-purpose address signals AAD0 through AADn supplied from an exterior. The memory 100 further includes a read/write circuit 105 for reading data from and writing data to the memory array 101 and an input and output circuit 106 for inputting input data DO0 through DOm into and outputting output data DI0 through DIm from the read/write circuit 105. The memory 100 further includes a spare memory cell 107, a spare decoder 108, a control circuit 109, and a repair match circuit 110, which serve as redundancy circuits.

In such a memory 100, when there is a failure in the memory array 101, information about the failed address is provided to the repair match circuit 110 as repair address signals RADD0 through RADDn. Further, a repair enable signal REN set in an enable state is supplied.

The settings of the repair address signals RADD0 through RADDn are defined in fuse circuits (not shown). In the fuse circuits, fuses provided on an address-line-specific basis may be cut by a laser repair apparatus or left intact, which determines whether the repair address signals RADD0 through RADDn are set to “1” or “0”.

Since the initial state of the fuses in the fuse circuit are also interpreted as address signal settings, the repair enable signal REN is set to an enable state when there is a failure in the memory array 101. If there is no failure in the memory array 101, the repair enable signal REN is set to a disable state. When the repair enable signal REN from the fuse circuits is in the enable state, and the access-purpose address signals AAD0 through AADn from the exterior match the repair address signals RADD0 through RADDn, the repair match circuit 110 enables an address match signal AGA for provision to the control circuit 109. The control circuit 109 activates an enable signal SDEN in response to the address match signal AGA supplied from the repair match circuit 110. The enable signal SDEN is supplied to the spare decoder 108. This activates the spare decoder 108, causing access to be performed with respect to the spare memory cell 107 rather than with respect to a failed memory cell. At this time, the control circuit 109 disables an enable signal LDEN supplied to the row decoder 102, preventing the row decoder 102 from accessing the memory cells of the memory array 101. With this provision, it is possible to access only the spare memory cell 107 when the repair address signals RADD0 through RADDn correspond to a failed memory cell in the memory array 101.

In the case of the memory 100 as described above, fuses in the fuse circuits need to be provided in a number corresponding to the number (n) of the repair address signals plus the number (1) of the enable signal. If 100 memories are provided on one chip, and all need to be recovered, a large number of fuses are necessary, making such recovery unpractical. Further, even if fuses are provided for all the 100 memories, there is little possibility of every one of the 100 memories being defective. In general, there may be only few defects, so that a majority of the fuse circuits ends up being unused.

Patent Document 1 discloses a method of reducing the number of fuses used. In this method, a test circuit is provided as a built-in circuit, and generates failure information, based on which the controller causes a corresponding memory to latch information about a failed address for recovery purposes.

Further, Patent Document 2 discloses a technology for reducing the number of fuses by letting the fuses be shared by a plurality of memories and by providing a programmable selecting circuit.
[Patent Document 1] Japanese Patent Application Publication No. 2002-25292
[Patent Document 2] Japanese Patent Application Publication No. 2002-74981

In the case of Patent Document 1 described above, there is a need to activate the test circuit without exception at the time of power-on. This may create a situation in which the system cannot use such functionality. Further, there is an increase in area size due to the provision of the test circuit.

Further, in the case of Patent Document 2, there is a need to program the selecting circuit. Also, there is a need to modify the selecting circuit each time the chip is designed, depending on the number of memories used. This results in a circuit increase.

Accordingly, there is a need for a semiconductor memory device, a fuse box circuit, and a semiconductor integrated circuit in which the number of fuses in fuse circuits and the relevant control circuit can be reduced.

### SUMMARY OF THE INVENTION

It is a general object of the present invention to provide a semiconductor memory device, a fuse box circuit, and a semiconductor integrated circuit that substantially obviate one or more problems caused by the limitations and disadvantages of the related art.

Features and advantages of the present invention will be presented in the description which follows, and in part will become apparent from the description and the accompanying drawings, or may be learned by practice of the invention according to the teachings provided in the description. Objects as well as other features and advantages of the present invention will be realized and attained by a semiconductor memory device, a fuse box circuit, and a semiconductor integrated circuit particularly pointed out in the specification in such full, clear, concise, and exact terms as to enable a person having ordinary skill in the art to practice the invention.

To achieve these and other advantages in accordance with the purpose of the invention, the invention provides a semiconductor memory device, which includes a first memory having a plurality of memory cells arranged in matrix, a second memory including a spare memory cell for a repair purpose, the spare memory cell of the second memory being operable to replace a memory cell of the first memory, a memory match unit configured to check whether memory information identifying the semiconductor memory device matches external memory information supplied from an exterior, a repair match unit configured to check, in response to a finding of a match by the memory match unit, whether an access address for accessing the first memory matches a repair address indicative of a failed cell position in the first memory, and a control unit configured to perform a control operation to access the second memory in response to a finding of a match by the repair match unit.

In the semiconductor memory device as described above, the memory match unit checks whether the memory information identifying the semiconductor memory device matches the external memory information. When a match is found by the memory match unit, the repair match unit checks whether the access address for accessing the first memory matches a repair address indicative of a failed cell position in the first memory. When a match is found by the repair match circuit, access to the second memory is performed.

When such semiconductor memory devices are used in a semiconductor integrated circuit, the external memory information indicative of a semiconductor memory device having a failed cell is output from a fuse box circuit, so that a fuse box circuit for outputting the repair address can be shared among the plurality of the semiconductor memory devices. This improves recovery efficiency with respect to the fuse box circuit.

Further, the memory information specific to the semiconductor memory device is assigned to the semiconductor memory device at the time of designing the use of the semiconductor memory device. This eliminates a limit to the number of semiconductor memory devices allocated to the fuse box circuit.

According to another aspect of the present invention, a semiconductor memory device includes a first memory having a plurality of memory cells arranged in matrix, a second memory including a spare memory cell for a repair purpose, the spare memory cell of the second memory being operable to replace a memory cell of the first memory, a repair match unit configured to check whether memory information identifying the semiconductor memory device contained in an access address for accessing the first memory matches external memory information supplied from an exterior, and to check whether the access address matches a repair address indicative of a failed cell position in the first memory, and an address conversion unit configured to convert the access address such as to access the second memory in response to a finding of a match by the repair match unit.

In the semiconductor memory device as described above, the repair match unit checks whether the memory information contained in the access address matches the external memory information, and checks whether the access address matches the repair address indicative of a failed cell position in the first memory. When a match is found by the repair match circuit, the address conversion unit converts the access address to access the second memory.

When such semiconductor memory devices are used in a semiconductor integrated circuit, the repair memory address indicative of a semiconductor memory device having a failed cell is output from a fuse box circuit, so that the fuse box circuit for outputting the repair address can be shared among the plurality of the semiconductor memory devices. This improves recovery efficiency with respect to the fuse box circuit.

Further, with such configuration of the semiconductor memory device, the repair match unit checks whether the memory information matches the external memory information. This eliminates a need to provide a memory match unit in the semiconductor memory device.

According to another aspect of the present invention, a fuse box circuit includes first fuse circuits operative to store a repair address of a failed cell contained in a semiconductor memory device, and one or more second fuse circuits configured to store identification information that identifies the semiconductor memory device.

The use of the fuse box circuit as described above makes it possible to increase the number of semiconductor memory devices to be repaired by a single fuse box circuit.

According to another aspect of the present invention, the fuse box circuit as described above further includes a decode circuit configured to decode the one or more outputs of the one or more second fuse circuits to output a plurality of enable signals.

The fuse box circuit as described above uses the decode circuit to generate the enable signals for enabling respective semiconductor memory devices. This eliminates a need to provide a memory match unit in each of the semiconductor memory devices.

According to another aspect of the present invention, a semiconductor integrated circuit includes a plurality of semiconductor memory devices each identical to the semiconductor memory device as described above, and the fuse box circuit as described above.

### BRIEF DESCRIPTION OF THE DRAWINGS

Other objects and further features of the present invention will be apparent from the following detailed description when read in conjunction with the accompanying drawings, in which:

FIG. 1 is a drawing showing the basic configuration of a semiconductor integrated circuit according to an embodiment of the present invention;

FIG. 2 is a block diagram showing the configuration of a memory according to a first embodiment;

FIG. 3 is a drawing showing an example of a memory match circuit;

FIG. 4 is a drawing showing an example of a repair match circuit;

FIG. 5 is a block diagram showing the configuration of a memory according to a second embodiment;

FIG. 6 is a drawing showing an example of the configuration of an address buffer;

FIG. 7 is a drawing showing another example of the configuration of a semiconductor integrated circuit;

FIG. 8 is a drawing showing the configuration of a repair enable signal generating circuit provided in a fuse box circuit;

FIG. 9 is a drawing showing an example of the configuration of a fuse circuit; and

FIG. 10 is a drawing showing the basic configuration of a related-art memory.

### DESCRIPTION OF THE PREFERRED EMBODIMENTS

In the following, embodiments of the present invention will be described with reference to the accompanying drawings.

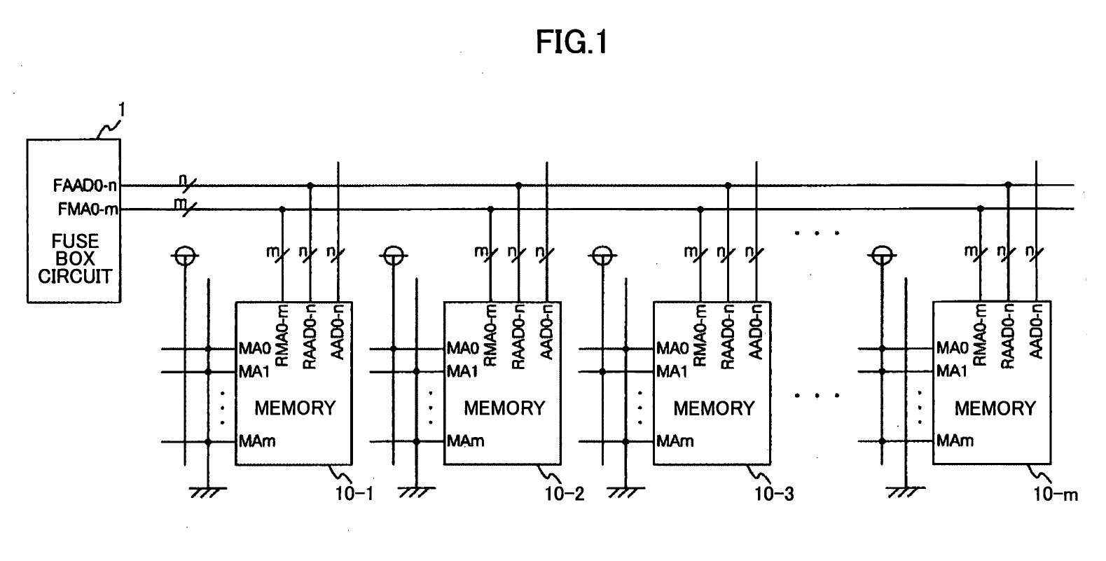

FIG. 1 is a drawing showing the basic configuration of a semiconductor integrated circuit according to an embodiment of the present invention.

A semiconductor integrated circuit shown in FIG. 1 includes a fuse box circuit 1 and a plurality of memories 10-1, 10-2, 10-3, . . . , and 10-m. Each of the memories 10-1 through 10-m receives address signals FMA0 through FMAm as repair memory address signals RMA0 through RMAm from the fuse box circuit 1, and also receives address signals FAAD0 through FAADn as repair address signals RAA0 through RAAn from the fuse box circuit 1. Further, each of the memories 10-1 through 10-m receives access-purpose address signals AAD0 through AADn from an exterior. Moreover, the memories 10-1 through 10-m have different memory identification address signals MA0 through MAm assigned thereto. The memory identification address signals MA0 through MAm are set to different addresses by coupling the input nodes of the memories 10-1 through 10-m directly to the power supply or GND. In the semiconductor integrated circuit described here, the number of the memories is limited by the number of bits of the memory identification address signals MA0 through MAm.

In this semiconductor integrated circuit, a test following the manufacturing of the circuit may find a failure in a memory cell of the memories 10-1 through 10-m. In such a case, programming is performed with respect to the repair memory address signals RMA0 through RMAm for indicating the memory where the failed memory cell is present and the repair address signals RAAD0 through RAADn corresponding to the address of the failed memory cell. To this end, a laser repair apparatus may be used to cut a relevant fuse in the fuse box circuit 1.

In the following, a description will be given of the configuration of a memory suitable as an embodiment of the semiconductor integrated circuit as described above.

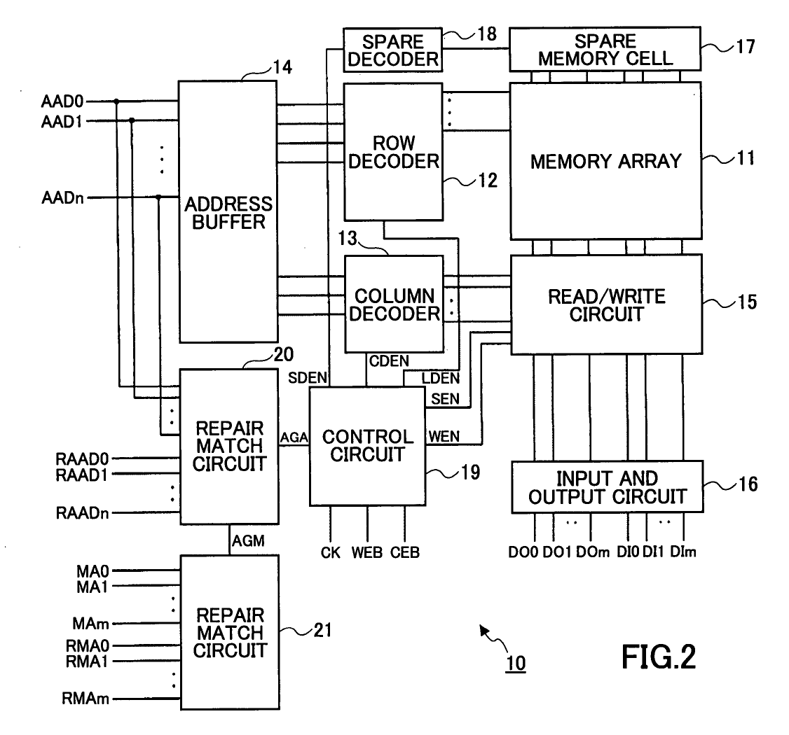

FIG. 2 is a block diagram showing the configuration of a memory according to a first embodiment. In this embodiment, one-port SRAM is used as an example of a memory device.

In FIG. 2, a memory array (first memory) 11 has a plurality of memory cells arranged in a matrix, each memory cell operative to store one-bit data therein. Each memory cell is provided at a predetermined address position determined by a row address and a column address. A row decoder 12 selects a row of the memory array 11 in response to a row address signal, and a column decoder 13 selects a column of the memory array 11 in response to a column address signal.

An address buffer 14 generates a row address signal and column address signal supplied to the row decoder 12 and column decoder 13, respectively, in response to access-purpose address signals AAD0 through AADn supplied from an exterior. A read/write circuit 15 reads stored data from the memory array 11, and writes data to the memory array 11. An input and output circuit 16 inputs input data DO0 through DOm into and outputs output data DI0 through DIm from the read/write circuit 15. A spare memory cell 17 has basically the same configuration as the memory array 11, except that the number of rows may be smaller than in the memory array 11. A spare decoder 18 selects a spare memory cell in response to an enable signal SDEN supplied from a control circuit 19. The control circuit 19 is configured to control the read/write circuit 15 based on a clock signal CK and the like and to control the operating states of the row decoder 12, the column decoder 13, and the spare decoder 18 in response to an address match signal AGA supplied from a repair match circuit 20.

The repair match circuit (repair check means) 20 compares the access-purpose address signals AAD0 through AADn supplied form the exterior with the repair address signals RAAD0 through RAADn supplied from the fuse box circuit 1 shown in FIG. 1. The repair match circuit 20 activates the address match signal AGA upon finding a match. Further, the repair match circuit 20 is configured to enter into an enable state in response to a memory match signal AGM supplied from a memory match circuit 21, which will be later described.

The memory match circuit (memory check means) 21 compares the memory identification address signals MA0 through MAm with the repair memory address signals RMA0 through RMAm supplied from the fuse box circuit 1. The memory match circuit 21 asserts the memory match signal AGM to the repair match circuit 20 upon finding a match.

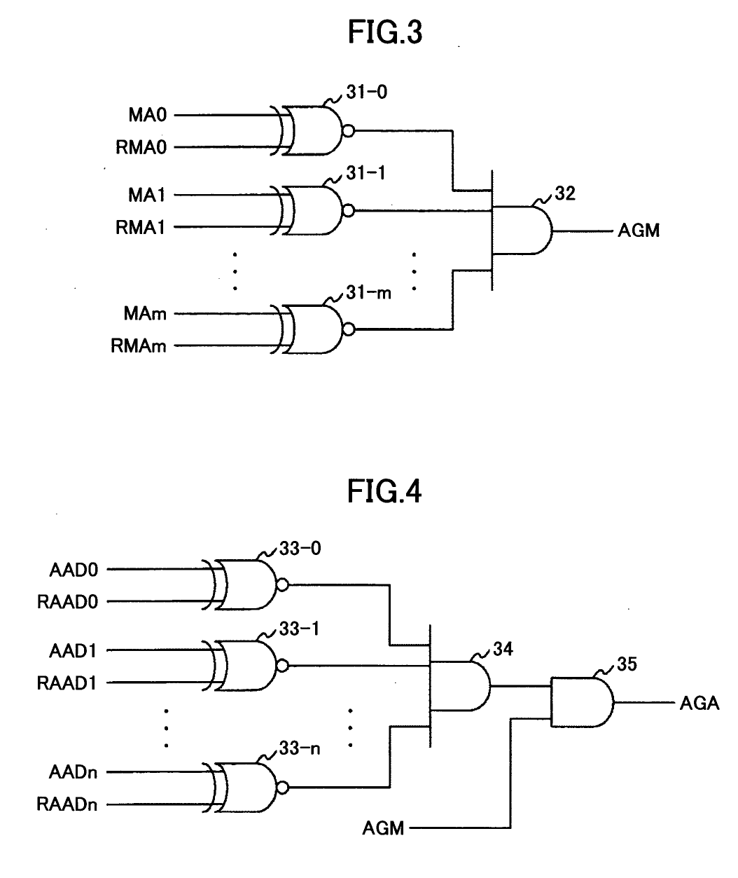

FIG. 3 is a drawing showing an example of the memory match circuit. The memory match circuit 21 shown in FIG. 3 uses an exclusive NOR gate (hereinafter referred to as “XNOR gate”) 31-0 to compare the memory identification address signal MA0 with the repair address signal RMA0. By the same token, an XNOR gate 31-1 is used to compare the memory address signal MA1 with the repair address signal RMA1. Further, an XNOR gate 31-m is used to compare the memory address signal MAm with the repair address signal RMAm. The output signals of the XNOR gates 31-0 through 31-m are supplied to an AND gate 32, an output signal of which is then supplied as the memory match signal AGM.

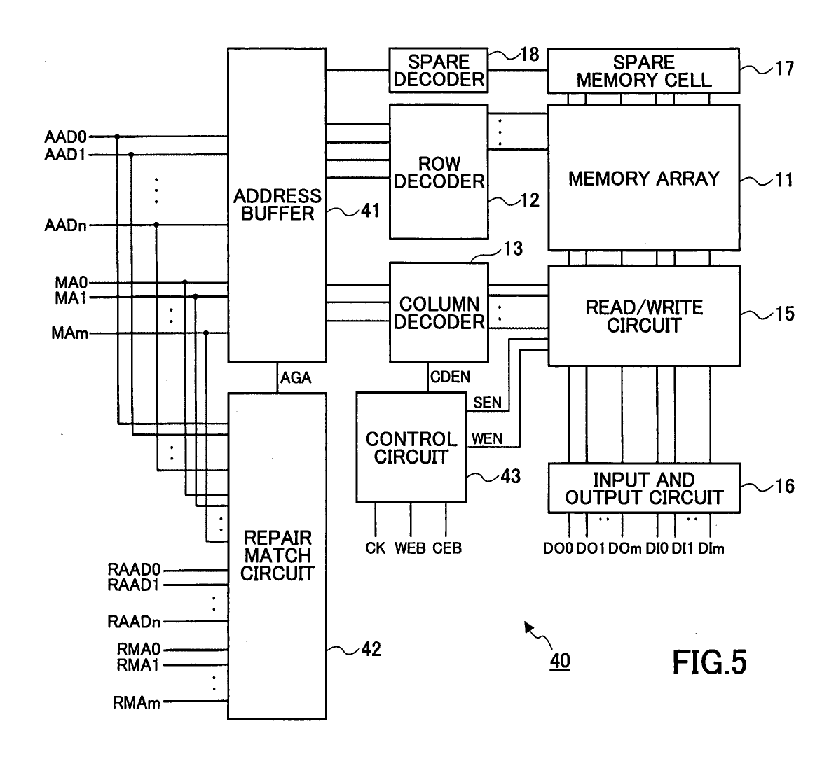

FIG. 4 is a drawing showing an example of the repair match circuit 20. The repair match circuit 20 shown in FIG. 4 uses an XNOR gate 33-0 to compare the access-purpose address signal AD0 with the repair address signal RAAD0. By the same token, an XNOR gate 33-1 is used to compare the access-purpose address signal AD1 with the repair address signal RAAD1. Further, an XNOR gate 33-n is used to compare the access-purpose address signal ADn with the repair address signal RAADn. The output signals of the XNOR gates 33-0 through 33-n are supplied to an AND gate 34, an output signal of which is then input into an AND gate 35 together with the memory match signal AGM. The output signal of the AND gate 35 is output as a repair match signal AGA.

In the following, a description will be given of the operation of the memory shown in FIG. 2. When an access is attempted with respect to a failed memory cell suffering a failure, the memory match circuit 21 finds a match between the repair memory address signals RMA0 through RMAm and the memory identification address signals MA0 through MAm. The memory match signal AGM thus becomes active, putting the repair match circuit 20 in an enable state.

In the enable state caused by the memory match signal AGM, the repair match circuit 20 activates the address match signal AGA in response to finding a match between the repair address signals RAA0 through RAAn and the access-purpose address signals AAD0 through AADn.

The control circuit 19 activates the enable signal SDEN supplied to the spare decoder 18 in response to the activation of the address match signal AGA, and also disables the enable signal LDEN supplied to the row decoder 12. In response, the spare decoder 18 activates a word line of the spare memory cell 17 to perform access.

At this time, with the enable signal LDEN of the row decoder 12 being disabled, the word lines of the memory array 11 are kept inactive. With this, the read/write circuit 15 performs data writing/reading. This makes it possible to access the spare memory cell 17 without accessing the failed cell of the memory array 11, thereby successfully avoiding the failed cell of the memory array 11.

When there is a failed cell in the memory array 11, access may be performed with respect to an address location other than that of the failed cell. In such a case, the memory match signal AGM produced by the memory match circuit 21 may stay in the enable state, but the address match signal AGA of the repair match circuit 20 does not become active because of a mismatch between the access-purpose address signals AAD0 through AADn and the repair address signals RAA0 through RAAn. As a result, the enable signal SDEN supplied from the control circuit 19 is not activated, so that the spare decoder 18 keeps the word lines inactive. No access to the spare memory cell 17 is thus performed. Further, the enable signal LDEN output from the spare decoder 18 stays active, so that access to the memory array 11 is properly performed.

When there is no failure in the memory array 11, access may be attempted with respect to the same address as the repair address signals RAAD0 through RAADn. In such a case, the memory match circuit 21 detects a mismatch, so that the enable signal AGM stays in the disable state. As a result, the repair match circuit 20 does not operate, and the address match signal AGA never becomes active. The control circuit 19 thus performs a routine operation.

In this manner, the memory match circuit 21 checks whether the memory identification address signal (memory information) MA0 through MAm defined on a memory-specific basis match the repair memory address signals (external memory information) RMA0 through RMAm supplied from the fuse box circuit 1. If they match, the repair match circuit 20 checks whether the access-purpose address signals AAD0 through AADn for accessing the memory array 11 match the repair address signals RAAD0 through RAADn indicative of a failed cell of the memory array 11. If they match, access to the spare memory cell 17 is performed.

When such memories 10-1 through 10-m are used in a semiconductor integrated circuit, the repair memory address signals RMA0 through RMAm indicative of a memory having a failed cell are output from the fuse box circuit 1, so that a fuse box circuit for outputting the repair address signals RAAD0 through RAADn can be shared among the plurality of the memories 10-1 through 10-m. This improves recovery efficiency with respect to the fuse box circuit 1.

With respect to such memories 10-1 through 10-m, the number of memories sharing the fuses can be increased to any desired extent by increasing the number of the memory address signals MAm and RMAm. A decision as to how many memories share fuses can freely be made at the time of chip design, depending on the size of memories actually needed.

FIG. 5 is a block diagram showing the configuration of a memory according to a second embodiment.

In a memory 40 shown in FIG. 5, the memory identification address signals MA0 through MAm are allocated to an upper-order portion of the actual memory address space. In this case, the configuration of an address buffer 41, a repair match circuit 42, and a control circuit 43 differs from that of the memory shown in FIG. 2.

The address buffer 41 generates a row address signal and column address signal supplied to the row decoder 12 and column decoder 13, respectively, in response to the access-purpose address signals AAD0 through AADn supplied from an exterior. When the address match signal AGA supplied from the repair match circuit 42 is active, the address buffer 41 converts the address signals such as to access the spare decoder 18 in response to the access-purpose address signals AAD0 through AADn. Namely, the address buffer 41 is provided with an address conversion circuit that converts the address into an address of a spare memory when the repair match circuit 42 asserts an active signal. The outputs are then supplied to the decoders.

The repair match circuit 42 activates and outputs the address match signal AGA when the repair memory address signals RMA0 through RMAm match the memory identification address signals MA0 through MAm, and, concurrently, the repair address signals RAAD0 through RAADn match the access-purpose address signals AAD0 through AADn.

The control circuit 43 controls the column decoder 13 and the read/write circuit 15 based on the clock signal CK and the like. Unlike the control circuit 19 shown in FIG. 2, the control circuit 43 in this embodiment does not control the row decoder 12, the column decoder 13, and the spare decoder 18 in response to the address match signal AGA supplied from the repair match circuit. Other configurations are the same as those of the memory shown in FIG. 2, and a description thereof will be omitted.

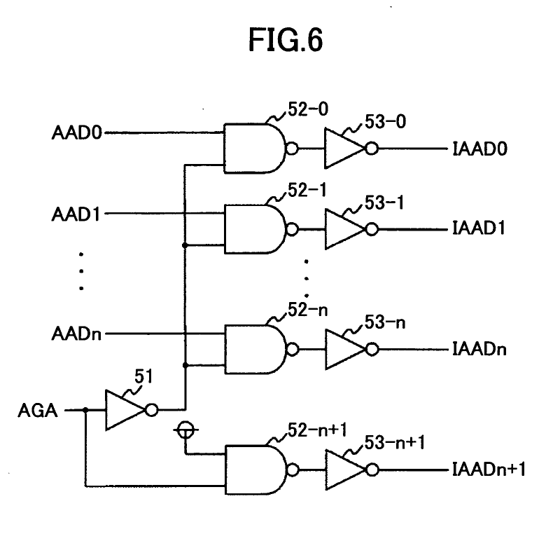

Here, with reference to FIG. 6, a description will be given of the address conversion circuit provided in the address buffer 41. The address buffer 41 forcibly converts the address in response to the activation of the repair match signal AGA supplied from the repair match circuit 42. To this end, the address buffer 41 is provided with an address space that has one more address line than the actual address space, and such address is assigned as the address of the spare decoder 18. In response to the repair match signal AGA (enable signal), the signal levels of the actual address portion are converted into “L”, and the signal level of the added signal line is converted into “H”. This makes it possible for the address buffer 41 to access an address outside the original address space.

FIG. 6 is a drawing showing an example of the configuration of the address buffer 41. The address buffer 41 shown in FIG. 6 has NAND gates 52-0 through 52-n, each of which receives an inverse of the repair match signal AGA inverted by an inverter 51, and further receives a corresponding one of the access-purpose address signals AAD0 through AADn. The outputs of the NAND gates 52-0 through 52-n are inverted by respective inverters 53-0 through 53-n to be output as address signals IAAD0 through IAADn.

Further, a NAND gate 52-n+1 receives the repair match signal AGA and the power supply voltage, and produces an output signal, which is inverted by an inverter 53-n+1 to be output as an address signal IAADn+1.

The operation of the memory 40 shown in FIG. 5 will be described here. When access is performed with respect to a failed cell of the memory suffering a failure, the repair match circuit 42 activates the address match signal AGA when the repair memory address signals RMA0 through RMAm match the memory identification address signals MA0 through MAm, and, concurrently, the repair address signals RAAD0 through RAADn match the access-purpose address signals AAD0 through AADn.

In response to the activation of the address match signal AGA from the repair match circuit 42, the address buffer 41 converts the address indicated by the access-purpose address signals by use of the circuit as shown in FIG. 6, thereby performing address conversion for accessing the spare decoder 18. In response, the spare decoder 18 activates a word line of the spare memory to access the spare memory cell 17. Since an address outside the original address space accessible by the row decoder 12 is being accessed, the row decoder 12 does not activate a word line of the memory array 11. Under these conditions, the input and output circuit 16 performs data writing/reading. It is thus possible to access the spare memory without accessing a failed address of the memory array, thereby successfully avoiding accessing the failed cell.

When there is a failed cell in the memory 40, access may be performed with respect to an address location other than that of the failed cell. In this case, the repair match circuit 42 does not detect a match, so that the address buffer 41 does not perform address conversion with respect to the access-purpose address signals AAD0 through AADn. Without the address conversion, the outputs of the address buffer 41 are supplied to the row decoder 12 and the column decoder 13, thereby allowing a memory cell of the memory array 11 to be accessed.

When there is no failed cell in the memory 40, access may be performed with respect to the same address location as the address indicated by the repair address signals RAAD0 through RAADn. In this case, the repair match circuit 42 does not detect a match, so that the address buffer 41 does not perform address conversion with respect to the access-purpose address signals AAD0 through AADn. Without the address conversion, the outputs of the address buffer 41 are supplied to the row decoder 12 and the column decoder 13, thereby allowing the memory array 11 to be accessed.

In this manner, the memory 40 according to the present embodiment uses the repair match circuit (repair check means) 42 to check whether the repair memory address signals (external memory information) RMA0 through RMAm match the memory identification address signals (memory information) MA0 through MAm allocated to the upper-order portion of the access-purpose address signals, and, concurrently, the repair address signals RAAD0 through RAADn match the access-purpose address signals AAD0 through AADn. If a match is detected, the address buffer 41 performs address conversion to access the spare memory cell 17.

When more than one such memory 40 is used in a semiconductor integrated circuit, the repair memory address signals RMA0 through RMAm indicative of a memory having a failed cell are output from the fuse box circuit 1, so that a fuse box circuit 1 for outputting the repair address signals RAAD0 through RAADn can be shared among the plurality of the memories 40. This improves recovery efficiency with respect to the fuse box circuit 1.

Further, in this configuration of the memory 40, the repair match circuit 42 checks whether there is a match between the memory identification address signals and the repair memory address signals. Because of this, there is no need to provide a memory match circuit in the memory 40.

Moreover, with respect to such memories 40, the number of memories sharing the fuses can be increased to any desired extent by increasing the number of the memory address signals MAm and RMAm. A decision as to how many memories share fuses can freely be made at the time of chip design, depending on the size of memories actually needed.

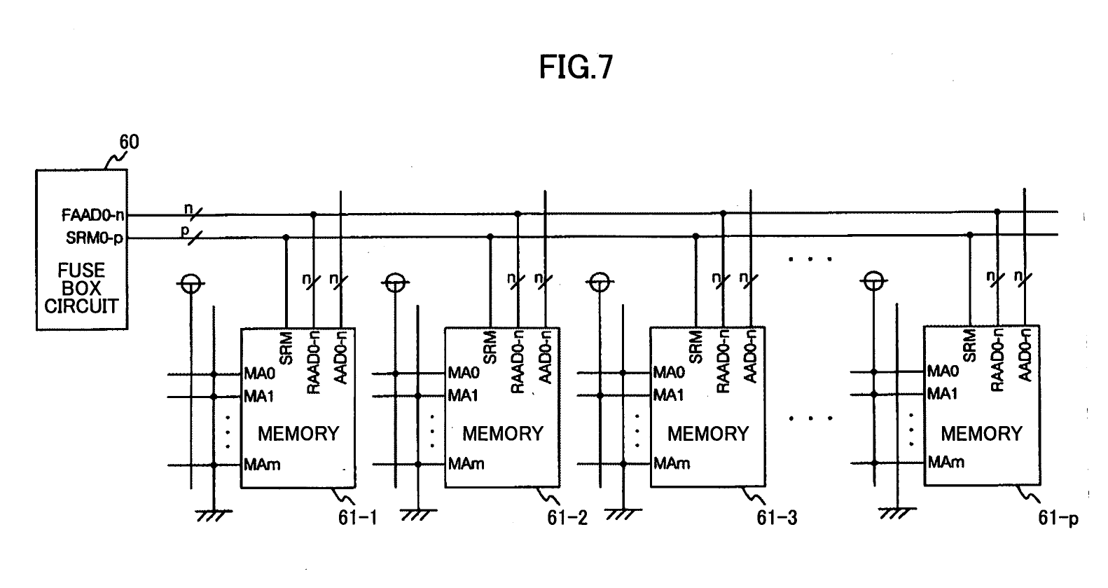

In the following, a description will be given of another configuration of a semiconductor integrated circuit according to an embodiment of the present invention with reference to FIG. 7.

The semiconductor integrated circuit shown in FIG. 7 includes a fuse box circuit 60 and a plurality of memories 61-1, 61-2, 61-3, . . . , and 61-p.

This embodiment differs from the semiconductor integrated circuit shown in FIG. 1 in that repair enable signals SRM0 through SRMP are supplied from the fuse box circuit 60 to the respective memories 61-1 through 61-p.

The fuse box circuit 60 is provided with, in addition to the fuse circuits, a repair enable signal generating circuit. The outputs of the fuse circuits are supplied as the repair address signals RAAD0 through RAADn to each of the memories 61-1 through 61-p, and a portion of the fuse circuits is decoded to generate the repair enable signals SRM0 through SRMp for selecting the respective memories. With this provision, a single fuse box circuit 60 can recover the plurality of memories 61-1 through 61-p. In this configuration, each of the memories 61-1 through 61-p receives a corresponding one of the repair enable signals SRM0 through SRMP, which controls whether to perform recovery if the repair address signals match.

With this configuration, there is no need to provide a match circuit in each of the memories 61-1 through 61-p. That is, the enable signal SRM can be used as the memory match signal AGM.

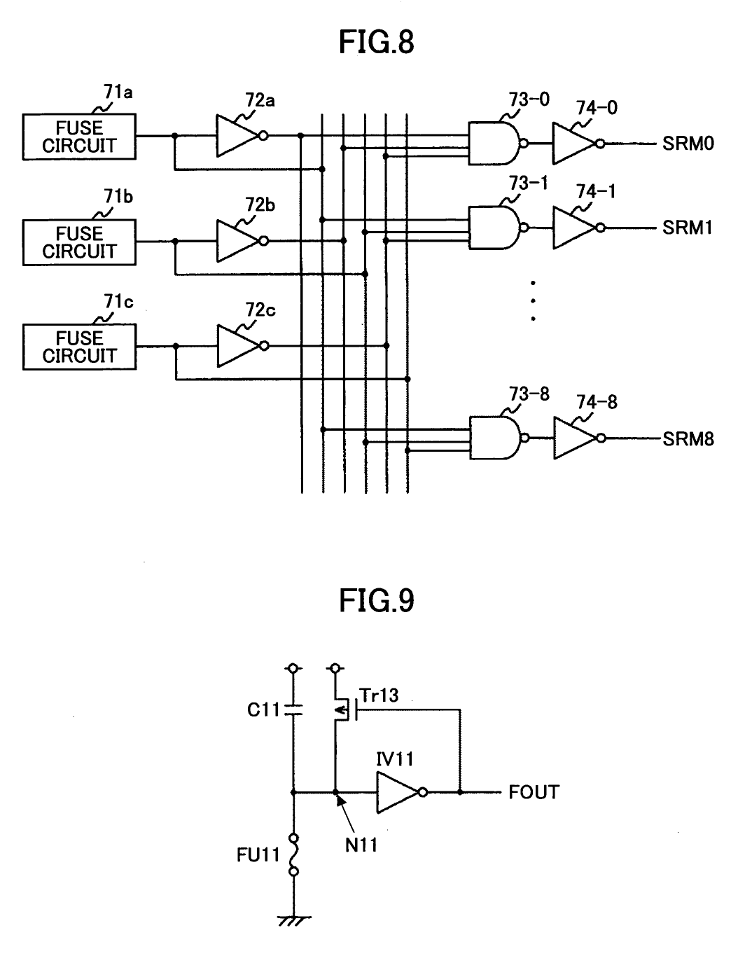

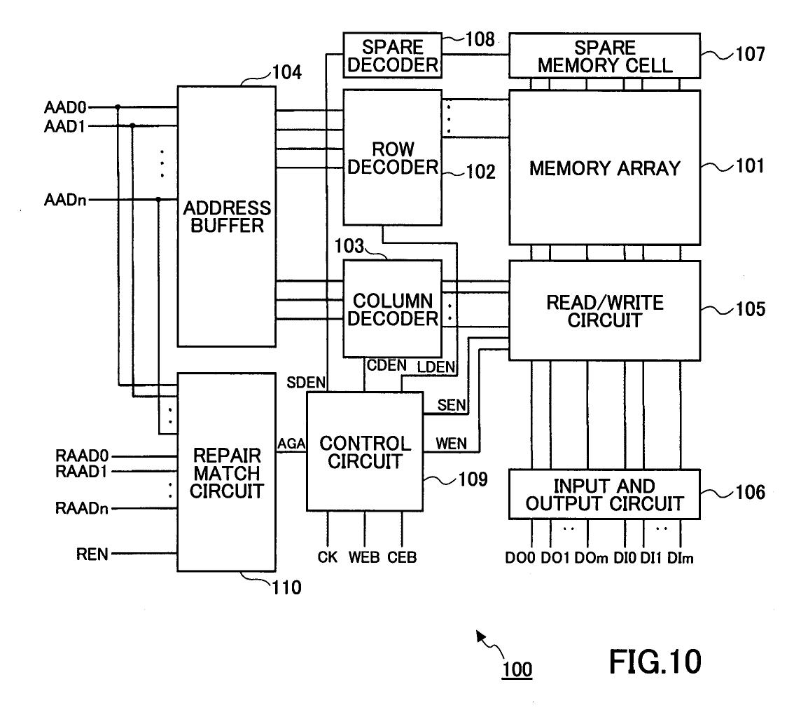

FIG. 8 is a drawing showing the configuration of the repair enable signal generating circuit provided in the fuse box circuit 60.

The repair enable signal generating circuit shown in FIG. 8 corresponds to an example in which the outputs of three fuse circuits 71a, 71b, and 71c are decoded to generate 8 enable signals SRM0 through SRM8. In this case, a NAND gate 73-0 receives the outputs of inverters 72a, 72b, and 72c that invert the respective outputs of the fuse circuits 71a, 71b, and 71c. Further, a NAND gate 73-1 receives the outputs of the fuse circuits 71a and 71b and the output of the inverter 72c that inverts the output of the fuse circuit 71c. Moreover, the NAND gate 73-8 receives the outputs of the fuse circuits 71a, 71b, and 71c. The outputs of the NAND circuits 73-0 through 73-8 are inverted by respective inverters 74-0 through 74-8 to be output as the enable signals SRM0 through SRM8. In the repair enable signal generating circuit shown in FIG. 8, the three fuse circuits 71a through 71c are used to generate the 8 repair enable signals SRM0 through SRM8. Without being limited to such configuration, any desired number of enable signals SRM may be generated by increasing the number of fuse circuits and decoding circuits.

FIG. 9 is a drawing showing an example of the configuration of a fuse circuit.

In the fuse circuit shown in FIG. 9, a node N11 is coupled to GND via a fuse FU11 to be set to the “L” level when the fuse FU11 is intact. Through the function of an inverter IV11, the output of the fuse circuit becomes the “H” level.

If the fuse FU11 is cut by use of the laser repair apparatus or the like, on the other hand, the node N11 becomes a floating node. In this case, as the power of the chip is switched on, and the power supply voltage is supplied, the potential at the node N11 is raised to the “H” level owing to the function of a capacitor C11. As a result, through the function of the inverter IV11, the output of the fuse circuit becomes the “L” level. Since the output of the inverter IV11 is coupled to the gate of a Pch-transistor Tr13, the Pch-transistor Tr13 is turned on. This results in the power supply voltage being supplied to the floating node N11, which helps to attain a stable voltage level.

The memories of the embodiments described above are directed to an example in which a spare cell is provided for the row address (on the word-line side). The present invention is equally applicable to a configuration in which a spare cell is provided on the column side.

Further, the embodiments have been described with respect to an example in which one-port SRAM is used as a semiconductor memory device. This is a non-limiting example, and the present invention is applicable to any SRAMs regardless of the number of ports. Moreover, the present invention is not limited to application to an SRAM, and is applicable to memories such as a DRAM.

Further, the present invention is not limited to these embodiments, but various variations and modifications may be made without departing from the scope of the present invention.

The present application is based on

Japanese priority application No. 2004-176104 filed on Jun. 14, 2004, with the Japanese Patent Office, the entire contents of which are hereby incorporated by reference.

1. A semiconductor memory device, comprising:
a first memory having a plurality of memory cells arranged in matrix;
a second memory including a spare memory cell for a repair purpose, the spare memory cell of said second memory being operable to replace a memory cell of said first memory;
a memory match unit configured to check whether memory information identifying said semiconductor memory device matches external memory information supplied from an exterior;
a repair match unit configured to check, in response to a finding of a match by said memory match unit, whether an access address for accessing said first memory matches a repair address indicative of a failed cell position in said first memory; and
a control unit configured to perform a control operation to access said second memory in response to a finding of a match by said repair match unit.

2. A semiconductor memory device, comprising:
a first memory having a plurality of memory cells arranged in matrix;
a second memory including a spare memory cell for a repair purpose, the spare memory cell of said second memory being operable to replace a memory cell of said first memory;
a repair match unit configured to check whether memory information identifying said semiconductor memory device contained in an access address for accessing said first memory matches external memory information supplied from an exterior, and to check whether the access address matches a repair address indicative of a failed cell position in said first memory; and
an address conversion unit configured to convert the access address such as to access said second memory in response to a finding of a match by said repair match unit.

3. A fuse box circuit, comprising:
first fuse circuits operative to store a repair address of a failed cell contained in a semiconductor memory device; and
one or more second fuse circuits configured to store identification information that identifies the semiconductor memory device.

4. The fuse box circuit as claimed in claim 3, further comprising a decode circuit configured to decode the one or more outputs of said one or more second fuse circuits to output a plurality of enable signals.

5. A semiconductor integrated circuit, comprising:
a plurality of semiconductor memory devices each identical to the semiconductor memory device of Claim 1; and
the fuse box circuit of claim 3.

6. A semiconductor integrated circuit, comprising:
a plurality of semiconductor memory devices each identical to the semiconductor memory device of claim 2; and
the fuse box circuit of claim 3.
